(19) United States
(12) Patent Application Publication
(10) Pub. No.: US 2024/0049609 A1
(43) Pub. Date: Feb. 8, 2024

(54) COUPLING COMPONENT APPLIED TO QUANTUM CHIP, QUANTUM CHIP AND QUANTUM COMPUTING DEVICE

(71) Applicant: Beijing Baidu Netcom Science Technology Co., Ltd., Beijing (CN)

(72) Inventors: Feiyu LI, Beijing (CN); Lijing JIN, Beijing (CN)

(21) Appl. No.: 18/126,035

(22) Filed: Mar. 24, 2023

(30) Foreign Application Priority Data
Aug. 8, 2022 (CN) 202210948015.5

(51) Int. Cl. H10N 60/80; H10N 60/12

(52) U.S. Cl. CPC H10N 60/805; H10N 60/12

(57) ABSTRACT

Provided is a coupling component applied to a quantum chip, a quantum chip and a quantum computing device. The coupling component includes a first electrode plate and a second electrode plate. The first electrode plate includes a first coupling port and a second coupling port. The second electrode plate includes a third coupling port and a fourth coupling port. At least one of the following conditions is satisfied: a first coupling strength formed by coupling the first coupling port with a first qubit is different from a second coupling strength formed by coupling the second coupling port with a second qubit, and a third coupling strength formed by coupling the third coupling port with the first qubit is different from a fourth coupling strength formed by coupling the fourth coupling port with the second qubit.

### CROSS-REFERENCE TO RELATED APPLICATIONS

The present application claims priority to Chinese Patent Application No. CN202210948015.5, filed with the China National Intellectual Property Administration on Aug. 8, 2022, the disclosure of which is hereby incorporated herein by reference in its entirety.

### TECHNICAL FIELD

The present disclosure relates to the field of computer technology, and, in particular, to the field of quantum chips and quantum computers.

### BACKGROUND

In order to achieve adjustable coupling between qubits, a tunable coupler architecture is introduced to significantly improve core performance indicators such as quantum gating speed and quantum gate fidelity of a quantum chip. Therefore, how to design a tunable coupler has become an important problem in the field of quantum chips.

### SUMMARY

The present disclosure provides a coupling component applied to a quantum chip, a quantum chip, and a quantum computing device.

According to an aspect of the present disclosure, provided is a coupling component applied to a quantum chip, including: a first electrode plate; and a second electrode plate electrically connected to the first electrode plate. The first electrode plate includes a first coupling port disposed at a first end of the first electrode plate and a second coupling port disposed at a second end of the first electrode plate; and the first coupling port is used to couple a first qubit, and the second coupling port is used to couple a second qubit; and the second electrode plate includes a third coupling port disposed at a first end of the second electrode plate and a fourth coupling port disposed at a second end of the second electrode plate; and the third coupling port is used to couple the first qubit, and the fourth coupling port is used to couple the second qubit. Formed coupling strengths satisfy at least one of: a first coupling strength formed by coupling the first coupling port with the first qubit is different from a second coupling strength formed by coupling the second coupling port with the second qubit; and a third coupling strength formed by coupling the third coupling port with the first qubit is different from a fourth coupling strength formed by coupling the fourth coupling port with the second qubit.

According to another aspect of the present disclosure, provided is a quantum chip, including: a coupling component, a first qubit and a second qubit, where the coupling component is the above-mentioned coupling component.

According to another aspect of the present disclosure, provided is a quantum computing device, including: a quantum chip, and a controller configured to control the quantum chip, where the quantum chip is the above-mentioned quantum chip.

Thus, a configuration of the coupling component with adjustable coupling strength is provided. Moreover, this configuration is very flexible and can be applicable to the requirement of long-distance coupling of qubits, and provides a new technical route for the design and development of quantum chips.

It should be understood that the content described in this part is not intended to identify key or important features of embodiments of the present disclosure, nor is it used to limit the scope of the present disclosure. Other features of the present disclosure will be easily understood by the following description.

### BRIEF DESCRIPTION OF THE DRAWINGS

The accompanying drawings are used to better understand the present solution, and do not constitute a limitation to the present disclosure.

FIG. 1 is a top view of a coupling component in a specific example according to an embodiment of the present disclosure.

FIG. 2 is a top view of a coupling component in another specific example according to an embodiment of the present disclosure.

FIG. 3 is a side view of a coupling component in a specific example according to an embodiment of the present disclosure.

FIG. 4 is a circuit diagram of an equivalent circuit of the coupling component according to an embodiment of the present disclosure.

FIG. 5 is a circuit diagram of an equivalent circuit of the coupling component according to an embodiment of the present disclosure.

FIG. 6 is a schematic diagram of the configuration of “qubit-coupler-qubit” according to an embodiment of the present disclosure.

FIG. 7 is a schematic diagram of variation characteristic of the coupling strength obtained by using the tunable coupler described in the solution of the present disclosure to adjust the coupling strength between two qubits.

### DETAILED DESCRIPTION

Hereinafter, descriptions to exemplary embodiments of the present disclosure are made with reference to the accompanying drawings, include various details of the embodiments of the present disclosure to facilitate understanding, and should be considered as merely exemplary. Therefore, those having ordinary skill in the art should realize, various changes and modifications may be made to the embodiments described herein, without departing from the scope and spirit of the present disclosure. Likewise, for clarity and conciseness, descriptions of well-known functions and structures are omitted in the following descriptions.

As a landmark technology in the post-Moore era, quantum computing has become an important development direction in academia and industry. In terms of some specific problems (for example, decomposition of large numbers, simulation of complex quantum systems, etc.), quantum computing shows incomparable advantages over traditional computing. The research on various high-potential quantum applications has greatly advanced the development of quantum hardware. In terms of hardware implementation, the industry has a variety of candidate technical solutions, including superconducting circuit, ion trap, diamond NV color center, nuclear magnetic resonance, optical quantum system, and so on. Benefiting from advantages such as long decoherence time, easy manipulation/reading and strong expandability, superconducting circuits are considered to be one of the most promising candidates for quantum computing hardware. With the advancement of micro-nano processing technology, the design and production of quantum chips integrating a plurality of qubits are becoming more and more important. In recent years, the domestic and foreign quantum computing technology companies/research institutions have successively developed superconducting quantum chips.

As the basic element of quantum chips, the qubit (quantum bit) usually consists of a capacitor and a Josephson junction in parallel. For the manipulation of a single qubit, a single-bit quantum gate can be realized. To realize a two-bit quantum gate, two qubits need to be coupled together. In order to achieve the tunable coupling between qubits (that is, achieve the “off” and “on” functions of the coupling as needed), a tunable coupler architecture is theoretically proposed.

Another important research shows that the correlation error between qubits decreases substantially as the distance between the qubits increases. More specifically, an experiment shows that the correlation error between qubits nearly disappears when the distance between the qubits is 3 mm. Moreover, the long distance between qubits can also greatly reduce the crosstalk between qubits, and at the same time, can also provide sufficient physical space for the design and wiring of core components such as a resonant cavity and filter. In short, the long-distance qubit design can not only improve the performance of a quantum chip, but also achieve greater freedom and more comprehensive functions of the entire design process.

However, existing couplers in the industry cannot take into account both “tunable coupler” and “long distance”, so the design of a tunable coupler with long-distance configuration has become a very important issue.

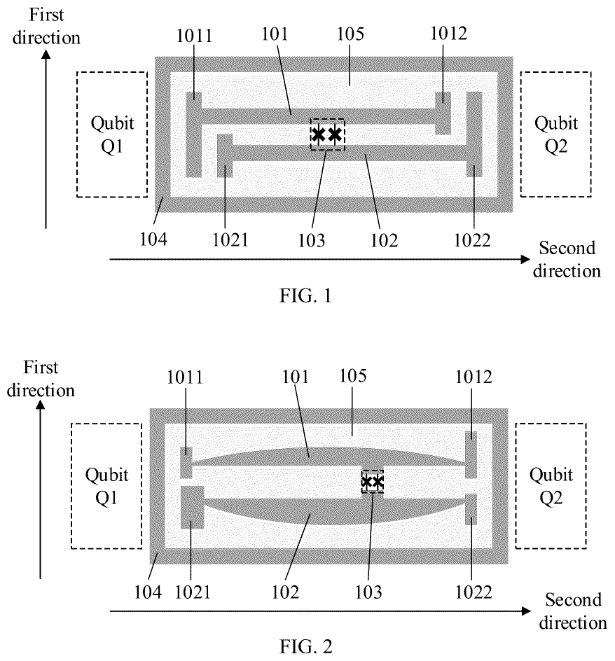

Based on this, the solution of the present disclosure proposes a novel tunable coupler configuration, specifically as shown in FIG. 1. A coupling component applied to a quantum chip, as shown in FIG. 1, includes: a first electrode plate 101; and a second electrode plate 102 electrically connected to the first electrode plate 101. The first electrode plate 101 includes a first coupling port 1011 disposed at a first end of the first electrode plate 101 and a second coupling port 1012 disposed at a second end of the first electrode plate 101; and the first coupling port 1011 is used to couple a first qubit (the qubit Q1 as shown in FIG. 1), and the second coupling port 1012 is used to couple a second qubit (the qubit Q2 as shown in FIG. 1). The second electrode plate 102 includes a third coupling port 1021 disposed at a first end of the second electrode plate 102 and a fourth coupling port 1022 disposed at a second end of the second electrode plate; and the third coupling port 1021 is used to couple the first qubit (the qubit Q1 as shown in FIG. 1), and the fourth coupling port 1022 is used to couple the second qubit (the qubit Q2 as shown in FIG. 1). The formed coupling strengths satisfy at least one of: a first coupling strength formed by coupling the first coupling port 1011 with the first qubit is different from a second coupling strength formed by coupling the second coupling port 1012 with the second qubit; and a third coupling strength formed by coupling the third coupling port 1021 with the first qubit is different from a fourth coupling strength formed by coupling the fourth coupling port 1022 with the second qubit.

That is to say, the solution of the present disclosure has three cases as follows.
Case 1: the first coupling strength formed by coupling the first coupling port 1011 with the first qubit is different from the second coupling strength formed by coupling the second coupling port 1012 with the second qubit.
It can be understood that, in this case, the third coupling strength formed by coupling the third coupling port 1021 with the first qubit may be the same as the fourth coupling strength formed by coupling the fourth coupling port 1022 with the second qubit.
Case 2: the third coupling strength formed by coupling the third coupling port 1021 with the first qubit is different from the fourth coupling strength formed by coupling the fourth coupling port 1022 with the second qubit.
It can be understood that, in this case, the first coupling strength formed by coupling the first coupling port 1011 with the first qubit may be the same as the second coupling strength formed by coupling the second coupling port 1012 with the second qubit.
Case 3: the first coupling strength formed by coupling the first coupling port 1011 with the first qubit is different from the second coupling strength formed by coupling the second coupling port 1012 with the second qubit, and the third coupling strength formed by coupling the third coupling port 1021 with the first qubit is different from the fourth coupling strength formed by coupling the fourth coupling port 1022 with the second qubit.

The solution of the present disclosure does not limit the three cases described above, and any one of the three cases described above is within the protection scope of the solution of the present disclosure.

Thus, a configuration of the coupling component with adjustable coupling strength is provided. Moreover, this configuration is very flexible and can be applicable to the requirement of long-distance coupling of qubits, and provides a new technical route for the design and development of quantum chips.

Further, since the solution of the present disclosure can be applicable to the requirement of long-distance coupling of qubits, on the one hand, the structural support can be provided for reducing the control crosstalk and correlation error between qubits; and on the other hand, the solution of the present disclosure can also provide a wide range of design space for the distribution of devices in the quantum chip. For example, in the design stage of the quantum chip, each qubit can have an independent read cavity and filter, so as to reduce the read crosstalk between qubits, and thus improve the performance of the quantum chip greatly.

In a specific example, the above-mentioned electrode plate may specifically be a superconducting metal plate. Further, the quantum chip may also be specifically a superconducting quantum chip. At this time, the solution of the present disclosure can also provide a new technical route for the design and development of the superconducting quantum chip.

It should be noted that the solution of the present disclosure does not limit the features such as length and shape of the coupling port as well as the features such as length and shape of the first or second electrode plate, which can be set based on actual scene requirements. In other words, it can be understood that the structure shown in FIG. 1 is only exemplary illustration but not intended to limit the solution of the present disclosure. In practical applications, the first and second electrode plates and the ports in the first and second electrode plates may also have a structure as shown in FIG. 2, which is not limited in the solution of the present disclosure.

In a specific example of the solution of the present disclosure, the first coupling strength formed by coupling the first port with the first qubit is greater than the second coupling strength formed by coupling the second coupling port with the second qubit; or the first coupling strength formed by coupling the first coupling port with the first qubit is less than the second coupling strength formed by coupling the second coupling port with the second qubit.

In this way, a coupling component with highly wide applicability is provided, to lay a foundation for flexibly adjusting the coupling strength between two qubits, and thus lay a foundation for improving the performance of the quantum chip.

In a specific example of the solution of the present disclosure, the third coupling strength formed by coupling the third coupling port with the first qubit is greater than the fourth coupling strength formed by coupling the fourth coupling port with the second qubit; or the third coupling strength formed by coupling the third coupling port with the first qubit is less than the fourth coupling strength formed by coupling the fourth coupling port with the second qubit.

In this way, a coupling component with highly wide applicability is provided, to lay a foundation for flexibly adjusting the coupling strength between two qubits, and thus lay a foundation for improving the performance of the quantum chip.

For example, when the first coupling strength is different from the second coupling strength and the third coupling strength is different from the fourth coupling strength, there are the following cases.
Case 1: the first coupling strength is greater than the second coupling strength, and the third coupling strength is greater than the fourth coupling strength. That is, the first coupling port and the third coupling port for coupling with the first qubit are both strong coupling ports, while the second coupling port and the fourth coupling port for coupling with the second qubit are both weak coupling ports.
It can be understood that the “strong” and “weak” described in the solution of the present disclosure are relative concepts and used to describe the coupling capabilities of different coupling ports in the same electrode plate; for example, when the first coupling strength is greater than the second coupling strength, the first coupling port of the first electrode plate may be called a strong coupling port, and the second coupling port of the first electrode plate may be called a weak coupling port. Similarly, when the third coupling strength is greater than the fourth coupling strength, the third coupling port of the second electrode plate may be called a strong coupling port, and the fourth coupling port of the second electrode plate may be called a weak coupling port.
Further, it should be noted that the solution of the present disclosure does not limit the strong and weak relationship of coupling ports in different electrode plates. For example, when the first coupling port is the strong coupling port in the first electrode plate and the third coupling port is the strong coupling port in the second electrode plate, the coupling strengths of the first and third coupling ports with the first qubit respectively may be the same or different, which is not limited in the solution of the present disclosure.

Case 2: the first coupling strength is greater than the second coupling strength, and the third coupling strength is less than the fourth coupling strength. That is, the first coupling port for coupling with the first qubit is a strong coupling port, while the third coupling port for coupling with the first qubit is a weak coupling port; and the second coupling port for coupling with the second qubit is a weak coupling port, while the fourth coupling port for coupling with the second qubit is a strong coupling port.
Case 3: the first coupling strength is less than the second coupling strength, and the third coupling strength is less than the fourth coupling strength. That is, the first coupling port and the third coupling port for coupling with the first qubit are both weak coupling ports, while the second coupling port and the fourth coupling port for coupling with the second qubit are both strong coupling ports.
Case 4: the first coupling strength is less than the second coupling strength, and the third coupling strength is greater than the fourth coupling strength. That is, the first coupling port for coupling with the first qubit is a weak coupling port, while the third coupling port for coupling with the first qubit is a strong coupling port; and the second coupling port for coupling with the second qubit is a strong coupling port, while the fourth coupling port for coupling with the second qubit is a weak coupling port.

It can be understood that the solution of the present disclosure does not specifically limit the above cases. In practical applications, the selection may be made based on specific requirements.

In a specific example of the solution of the present disclosure, the total coupling strength formed by the coupling component and the first qubit is the same as or different from the total coupling strength formed by the coupling component and the second qubit.

It can be understood that the total coupling strength formed with the first qubit includes the first coupling strength formed by the first coupling port of the first electrode plate and the first qubit, and the third coupling strength formed by the third coupling port of the second electrode plate and the first qubit.

Similarly, the total coupling strength formed with the second qubit includes the second coupling strength formed by the second coupling port of the first electrode plate and the second qubit, and the fourth coupling strength formed by the fourth coupling port of the second electrode plate and the second qubit.

In this way, a coupling component with highly wide applicability is provided, to lay a foundation for flexibly adjusting the coupling strength between two qubits, and thus lay a foundation for improving the performance of the quantum chip.

In a specific example of the solution of the present disclosure, the coupling component is a symmetrical coupler. For example, in the scenario where the total coupling strength formed by the coupling component and the first qubit may be the same as the total coupling strength formed by the coupling component and the second qubit, for example, for the scenario of the above case 2 or 4, the total coupling strength formed by the coupling component and the first qubit may be the same as the total coupling strength formed by the coupling component and the second qubit. At this time, the coupling component described in the solution of the present disclosure may be specifically a symmetrical coupler, thus enriching the usage scenarios of the solution of the present disclosure and further laying a foundation for being suitable for the requirement of long-distance coupling of qubits.

In a specific example of the solution of the present disclosure, the first electrode plate and the second electrode plate are arranged at interval in a first direction. For example, as shown in FIG. 1, the first direction is the longitudinal direction. At this time, the first electrode plate 101 and the second electrode plate 102 are arranged at interval in the longitudinal direction.

It should be noted that the solution of the present disclosure does not specifically limit the interval between the two electrode plates, which can be set based on actual scene requirements.

In this way, an inter-plate configuration that is a simple configuration and is easy for engineering promotion is provided, to lay a foundation for expanding the scale of the quantum chip and enabling the quantum chip to have a larger wiring space, and also provide structural support for being more suitable for long-distance coupling of qubits.

In a specific example of the solution of the present disclosure, a first orthographic projection of the first electrode plate on a specific plane at least partially overlaps with a second orthographic projection of the second electrode plate on the specific plane, where the specific plane is perpendicular to the first direction. For example, the first electrode plate and the second electrode plate are arranged correspondingly. At this time, the orthographic projections of the two electrode plates on a specific plane partially or completely overlap, thus providing structural support for being more suitable for long-distance coupling of qubits.

In a specific example of the solution of the present disclosure, a body of the first electrode plate extends in a second direction different from the first direction, so that the first end of the first electrode plate and the second end of the first electrode plate are arranged in the second direction, thus providing structural support for being more suitable for long-distance coupling of qubits.

In an example, as shown in FIG. 1 or FIG. 2, the second direction may specifically be the horizontal direction. At this time, the body of the first electrode plate 101 extends in the second direction, so that the first coupling port 1011 and the second coupling port 1012 of the first electrode plate 101 are also arranged in the second direction.

It can be understood that the structure shown in FIG. 1 is only exemplary illustration. In practical applications, the length and shape of the body of the first electrode plate may be set based on actual requirements, which are not specifically limited in the solution of the present disclosure. For example, as shown in FIG. 2, the body of the first electrode plate may also be non-rectangular, etc.

In a specific example of the solution of the present disclosure, the first coupling port and the third coupling port for coupling with the first qubit are aligned or misaligned in the first direction. For example, as shown in FIG. 1, the first coupling port 1011 and the third coupling port 1021 are misaligned; for another example, as shown in FIG. 2, the first coupling port 1011 and the third coupling port 1021 are arranged correspondingly, thus providing structural support for being more suitable for long-distance coupling of qubits.

In a specific example of the solution of the present disclosure, a body of the second electrode plate extends in a second direction different from the first direction, so that the first end of the second electrode plate and the second end of the second electrode plate are arranged in the second direction, thus providing structural support for being more suitable for long-distance coupling of qubits.

In an example, as shown in FIG. 1 or FIG. 2, the second direction may specifically be the horizontal direction. At this time, the body of the second electrode plate 102 extends in the second direction, so that the third coupling port 1021 and the fourth coupling port 1022 of the second electrode plate 102 are also arranged in the second direction.

It can be understood that the structure shown in FIG. 1 is only exemplary illustration. In practical applications, the length and shape of the body of the second electrode plate may be set based on actual requirements, which are not specifically limited in the solution of the present disclosure. For example, as shown in FIG. 2, the body of the second electrode plate may also be non-rectangular, etc.

In a specific example of the solution of the present disclosure, the second coupling port and the fourth coupling port for coupling with the second qubit are aligned or misaligned in the first direction. For example, as shown in FIG. 1, the second coupling port 1012 and the fourth coupling port 1022 are misaligned; for another example, as shown in FIG. 2, the second coupling port 1012 and the fourth coupling port 1022 are arranged correspondingly, thus providing structural support for being more suitable for long-distance coupling of qubits.

In a specific example of the solution of the present disclosure, as shown in FIG. 1 and FIG. 2, the coupling component further includes: a quantum interference device 103 arranged between the first electrode plate 101 and the second electrode plate 102 and configured to electrically connect the first electrode plate 101 to the second electrode plate 102.

In a specific example, the quantum interference device 103 is a Superconducting Quantum Interference Device (SQUID).

In this way, a coupling component with highly wide applicability is provided, to lay a foundation for flexibly adjusting the coupling strength between two qubits, and thus lay a foundation for improving the performance of the quantum chip.

In a specific example of the solution of the present disclosure, the quantum interference device includes two Josephson junction chains in parallel, and the Josephson junction chains are connected to the first electrode plate and the second electrode plate respectively. In this way, a coupling component with highly wide applicability is provided, to lay a foundation for flexibly adjusting the coupling strength between two qubits, and thus lay a foundation for improving the performance of the quantum chip.

In a specific example of the solution of the present disclosure, the Josephson junction chain contains at least one Josephson junction. For example, as shown in FIG. 1 or FIG. 2, each of the Josephson junction chains contains one Josephson junction. It can be understood that FIG. 1 and FIG. 2 are only exemplary illustration. In practical applications, a plurality of Josephson junctions may also be included, which is not limited in the solution of the present disclosure.

In this way, a coupling component with highly wide applicability is provided, to lay a foundation for flexibly adjusting the coupling strength between two qubits, and thus lay a foundation for improving the performance of the quantum chip.

In a specific example of the solution of the present disclosure, when the Josephson junction chain contains two or more Josephson junctions, the two or more Josephson junctions are connected in series. In this way, a coupling component with highly wide applicability is provided, to lay a foundation for flexibly adjusting the coupling strength between two qubits, and thus lay a foundation for improving the performance of the quantum chip.

In a specific example of the solution of the present disclosure, the quantities of Josephson junctions contained in different Josephson junction chains are same or different. In this way, a coupling component with highly wide applicability is provided, to lay a foundation for flexibly adjusting the coupling strength between two qubits, and thus lay a foundation for improving the performance of the quantum chip.

In a specific example of the solution of the present disclosure, a coplanar capacitance can be formed between the first electrode plate 101 and the second electrode plate 102. In this way, a coupling component with highly wide applicability is provided, to lay a foundation for flexibly adjusting the coupling strength between two qubits, and thus lay a foundation for improving the performance of the quantum chip.

In a specific example of the solution of the present disclosure, a frequency adjustment of the coupling component is capable of adjusting a coupling strength between the first qubit and the second qubit during operation of the coupling component. In this way, the coupling component described in the solution of the present disclosure may be used as a tunable coupler, laying a foundation for flexibly adjusting the coupling strength between two qubits, and thus laying a foundation for improving the performance of the quantum chip.

In a specific example of the solution of the present disclosure, a frequency adjustment of the coupling component is capable of turning on or off coupling between the first qubit and the second qubit during operation of the coupling component.

In this way, the solution of the present disclosure provides a coupling component suitable for the case of long-distance coupling of qubits, and can realize the coupling of two qubits within the interval in which the frequency of the coupling component is lower than that of qubits, to thereby realize turning on and off the coupling of two qubits.

In a specific example of the solution of the present disclosure, an adjustment of a magnetic flux of the quantum interference device is capable of adjusting a frequency of the coupling component during operation of the coupling component. In this way, a simple and feasible solution for adjusting the frequency of the coupling component is provided, to thereby provide support for implementation of adjusting the coupling strength between two qubits and implementation of turning on and off the coupling of two qubits.

In a specific example of the solution of the present disclosure, as shown in FIG. 1 or FIG. 2, the coupling component further includes an external electrode plate 104 for grounding, and the external electrode plate 104 is arranged on the periphery of the first electrode plate 101 and the second electrode plate 102 and surrounds the first electrode plate 101 and the second electrode plate 102, thus forming a floating ground structure. In this way, a coupling component with highly wide applicability is provided, to lay a foundation for flexibly adjusting the coupling strength between two qubits, and thus lay a foundation for improving the performance of the quantum chip.

In a specific example of the solution of the present disclosure, the coupling component is a floating ground coupler. In this way, a floating ground coupler with highly wide applicability is provided, to lay a foundation for flexibly adjusting the coupling strength between two qubits, and thus lay a foundation for improving the performance of the quantum chip.

To sum up, the coupling component provided in the solution of the present disclosure has the following advantages.
1. Highly wide applicability. Compared with other tunable coupler configurations, the solution of the present disclosure is more suitable for the case of long-distance coupling of qubits. The coupling component described in the solution of the present disclosure can realize the coupling of two qubits in the interval in which the frequency of the coupling component is lower than that of qubits, and can realize turning on and off the coupling of two qubits. Moreover, for the coupling component provided in the solution of the present disclosure, the longer the distance, the larger the capacitance and the lower its own frequency, so that the frequency condition of coupling of qubits can be better satisfied, and on this basis, the coupling requirement of qubits, including the turning-off condition and the certain coupling strength, can be better satisfied.
2. The performance of the quantum chip can be improved. The quantum chip (such as superconducting quantum chip) using the coupling component of the solution of the present disclosure may also use the long-distance coupling architecture, thus, on the one hand, helping to reduce the control crosstalk and correlation error between qubits; and on the other hand, also providing a wide range of space for distribution of devices. For example, each qubit can have an independent read cavity and filter, reducing the read crosstalk between qubits, and thus improving the performance of the quantum chip greatly.
3. Help to expand the scale of the quantum chip. The quantum chip using the coupling component of the solution of the present disclosure can use the long-distance coupling architecture, so the quantum chip has a larger wiring space, and then the quantity of qubits can be further increased (the quantity of measurement and control lines will increase as the quantity of qubits increases), thereby increasing the scale of the quantum chip.
4. Simplify the design requirements of the quantum chip. After adopting the coupling component of the solution of the present disclosure, each qubit has space to place an independent read cavity and filter, so there is no need to design a read cavity or filter multiplexed by multiple qubits, thus reducing the design complexity of the quantum chip greatly.

The solution of the present disclosure further provides a quantum chip, including: a coupling component which is the coupling component described above, a first qubit and a second qubit.

In this way, benefiting from the introduction of the tunable coupling component of the solution of the present disclosure, the core performance indicators such as quantum gating speed and quantum gate fidelity of the quantum chip can be significantly improved.

Further, due to the use of the tunable coupling component of the solution of the present disclosure, the advantages of long-distance coupling between qubits can be fully utilized. Also, in terms of performance, the crosstalk and correlation error between qubits in the quantum chip can be reduced; and in terms of layout, a wide space can also be provided for wiring and device distribution, thus providing a new technical route for the design and development of the high-performance quantum chip (such as high-performance superconducting quantum chip).

The solution of the present disclosure further provides a quantum computing device, including: a quantum chip which is the quantum chip described above, and a controller configured to control the quantum chip.

In this way, benefiting from the introduction of the tunable coupling component of the solution of the present disclosure, the core performance indicators such as quantum gating speed and quantum gate fidelity in the quantum computing device can be significantly improved.

Further, due to the use of the tunable coupling component of the solution of the present disclosure, the advantages of long-distance coupling between qubits can be fully utilized. Also, in terms of performance, the crosstalk and correlation error between qubits in the quantum chip can be reduced, and at the same time, the wide space can also be provided for wiring and device distribution.

The solution of the present disclosure will be further described in detail below with reference to specific examples. Specifically, the solution of the present disclosure provides a novel tunable coupler of floating ground type, including two electrode plates in an upper and lower configuration, and each electrode plate has two coupling ports coupling with qubits. For each electrode plate, the two coupling ports may be divided into a strong coupling port and a weak coupling port according to the coupling strength; and in practical applications, the tunable coupler of floating ground type may form a symmetrical tunable coupler of floating ground type according to the position distribution of ports of different types.

Thus, the tunable coupler of floating ground type described in the solution of the present disclosure can be perfectly applied to the long-distance coupling scenarios. Moreover, under the condition of satisfying the long distance, the tunable coupler of floating ground type in the solution of the present disclosure also has the following frequency feature that the frequency of the tunable coupler of floating ground type is less than the qubit frequency, so as to realize turning on and off the coupling between two qubits, and also provide the tunable coupling strength when the coupling is turned on.

Moreover, the tunable coupler of floating ground type in the solution of the present disclosure can give full play to the advantages of long-distance coupling between qubits. Thus, in terms of performance, the crosstalk and correlation error between qubits in the quantum chip can be reduced effectively; and in terms of layout of the quantum chip, a wide space can be provided for wiring and device distribution.

It should be noted that the electrode plate may specifically be a superconducting metal plate in this example.

Further, the content of the solution of the present disclosure will be described in detail from several parts below. The Part I introduces the configuration of the tunable coupler of floating ground type proposed in the solution of the present disclosure; and the Part II demonstrates the validity and advantages of the configuration of the tunable coupler of floating ground type in the solution of the present disclosure.

### Part I

The tunable coupler of floating ground type in the solution of the present disclosure includes: two electrode plates distributed up and down; and both ends of each electrode plate have a strong coupling port and a weak coupling port, and the coupling ports coupling with a same qubit in the two electrode plates are aligned or misaligned.

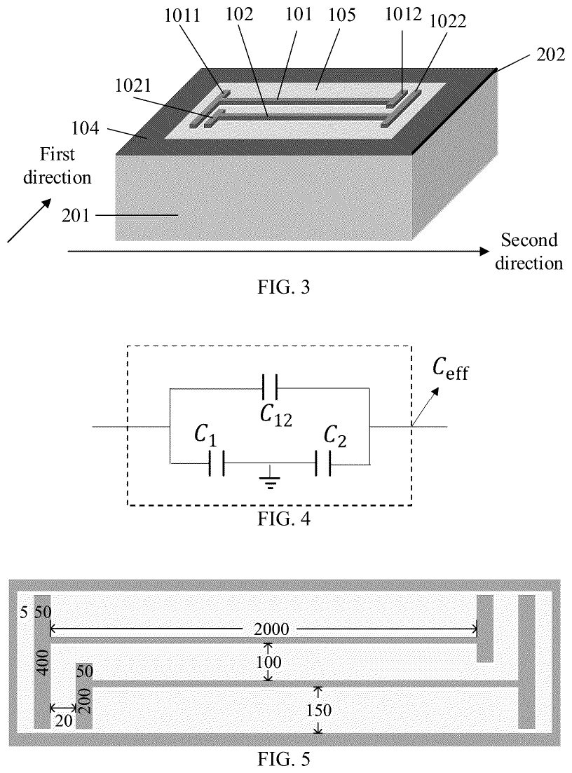

Specifically, as shown in FIG. 3, a metal layer 202, such as a superconducting metal layer, is formed on a substrate electrode plate 201, and the middle region 108 of the superconducting metal layer is etched to obtain the configuration pattern of the tunable coupler of floating ground type.

Further, as shown in FIG. 1 or FIG. 2, the interior of the tunable coupler of floating ground type includes two electrode plates, such as the first electrode plate 101 and the second electrode plate 102; and further, the first electrode plate 101 and the second electrode plate 102 are connected through a Superconducting Quantum Interference Device (SQUID) 103 arranged between the first electrode plate 101 and the second electrode plate 102. The tunable coupler of floating ground type further includes an external metal plate 104 for grounding, where the external metal plate 104 surrounds the first electrode plate 101 and the second electrode plate 102 to form a floating ground structure.

Here, the superconducting quantum interference device 103 includes two Josephson junction chains in parallel; and each of the Josephson junction chains is connected to the first electrode plate 101 and the second electrode plate 102 respectively; and further, the Josephson junction chain contains at least one Josephson junction. In an example, as shown in FIG. 1 or FIG. 2, each Josephson junction chain contains one Josephson junction, and each Josephson junction chain is connected to the first electrode plate 101 and the second electrode plate 102 respectively.

It can be understood that the above Josephson junction chain is only illustrative. In practical applications, the solution of the present disclosure does not limit the quantity of Josephson junctions in the Josephson junction chain, and the quantities of Josephson junctions contained in different Josephson junction chains are same or different.

Further, as shown in FIG. 1 or FIG. 2, the first electrode plate 101 and the second electrode plate 102 are arranged at interval in the first direction. Here, it can be understood that the solution of the present disclosure does not limit the distance between the two electrode plates, which can be set based on actual conditions.

Here, in an example, the first direction may specifically be the longitudinal direction.

Further, the first electrode plate 101 includes two coupling ports, namely a first coupling port 1011 and a second coupling port 1012, where the first coupling strength formed by coupling the first coupling port 1011 with the first qubit Q1 is greater than the second coupling strength formed by coupling the second coupling port 1012 with the second qubit Q2, that is, in the first electrode plate 101, the first coupling port 1011 on the left side is a strong coupling port, and the second coupling port 1012 on the right side is a weak coupling port.

Further, the second electrode plate 102 includes two coupling ports, namely a third coupling port 1021 and a fourth coupling port 1022, where the third coupling strength formed by coupling the third coupling port 1021 with the first qubit Q1 is less than the fourth coupling strength formed by coupling the fourth coupling port 1022 with the second qubit Q2, that is, in the second electrode plate 102, the third coupling port 1021 on the left side is a weak coupling port, and the fourth coupling port 1022 on the right side is a strong coupling port.

Here, the body of the first electrode plate 101 extends in the second direction different from the first direction, so that the first end of the first electrode plate 101 and the second end of the first electrode plate 101 are arranged in the second direction, that is, the first coupling port 1011 and the second coupling port 1012 of the first electrode plate 101 are arranged in the second direction.

Further, the body of the second electrode plate 102 extends in the second direction different from the first direction, so that the first end of the second electrode plate 102 and the second end of the second electrode plate 102 are arranged in the second direction, that is, the third coupling port 1021 and the fourth coupling port 1022 of the second electrode plate 102 are arranged in the second direction.

Further, the first coupling port 1011 and the third coupling port 1021 for coupling with the first qubit Q1 are aligned or misaligned.

Here, in a specific example, the second direction may specifically be the horizontal direction.

Further, the first qubit Q1 and the second qubit Q2 are also arranged in the second direction, so that it is convenient to indirectly couple the first qubit Q1 and the second qubit Q2 through the tunable coupler of floating ground type.

It should be noted that the above description that the first direction is the longitudinal direction, and the second direction is the horizontal direction is only exemplary description. In practical applications, there may also be other setting methods, which are not limited in the solution of the present disclosure.

During the operation of the tunable coupler of floating ground type, the tunable coupler of floating ground type can adjust the coupling strength between the first qubit Q1 and the second qubit Q2. For example, the coupling strength between the first qubit Q1 and the second qubit Q2 is adjusted by adjusting the frequency of the tunable coupler of floating ground type. Further, the frequency of the tunable coupler of floating ground type is adjusted by adjusting the magnetic flux of the superconducting quantum interference device 103, to thereby adjust the coupling strength between the first qubit Q1 and the second qubit Q2, and also realize turning on or off the coupling between the first qubit Q1 and the second qubit Q2.

In this way, the first qubit Q1 is respectively coupled with a strong coupling port (such as the first coupling port 1011) and a weak coupling port (such as the third coupling port 1021), and the second qubit Q2 is also respectively coupled with a strong coupling port (such as the fourth coupling port 1022) and a weak coupling port (such as the second coupling port 1012), so the coupler described in the solution of the present disclosure is also specifically a symmetrical tunable coupler.

It should be noted that the configuration of the solution of the present disclosure is not limited, for example, the shape of the electrode plate, the size of the electrode plate, the shape of the coupling port, the size of the coupling port, the horizontal or vertical distance between the electrode plate and the ground, and the position and size of the SQUID can be set according to the specific coupling situation. In other words, as long as two electrode plates are arranged at interval in the first direction and connected through the SQUID, and at least one electrode plate includes a weak coupling port and a strong coupling port, then the tunable couplers with this configuration are all within the protection scope of the solution of the present disclosure. For example, the tunable coupler of floating ground type as shown in FIG. 2 is also within the protection scope of the solution of the present disclosure.

### Part II

The core advantage of the tunable coupler configuration of floating ground type in the solution of the present disclosure is that it can be perfectly applicable to the case of long-distance coupling of qubits, which is specifically reflected in the following three points.
(1) Under the long distance condition (for example, when the lengths of the body of the first electrode plate M1 and the body of the second electrode plate M2 are greater than the preset length), the tunable coupler configuration of floating ground type described in the solution of the present disclosure can fully satisfy the frequency condition that the frequency (such as eigenfrequency) of the tunable coupler of floating ground type is less than the frequency (such as eigenfrequency) of the qubit; and the longer the distance, the less the frequency (such as eigenfrequency) of the tunable coupler of floating ground type.
(2) Under the long distance condition (for example, when the lengths of the body of the first electrode plate M1 and the body of the second electrode plate M2 are greater than the preset length), the tunable coupler of floating ground type described in the solution of the present disclosure can satisfy the turning-on and off conditions of coupling between two qubits (such as the first qubit and the second qubit) and can provide a certain coupling strength when the coupling is turned on, and this coupling strength is adjustable.
(3) Under the long distance condition, it is more universal than the general tunable coupler configuration and has more adjustable degrees of freedom, for example, the length and shape of the body of the first or second electrode plate, the length and shape of the coupling port, etc. can be freely adjusted based on actual requirements.

As shown in FIG. 5, it is an equivalent circuit of the tunable coupler of floating ground type shown in FIG. 1 or FIG. 2; and further, the equivalent total capacitance C_{eff} of the tunable coupler of floating ground type can be obtained, according to the series-parallel relationship of capacitances in the equivalent circuit, as:

$${C}_{off} = \frac{1}{\frac{1}{{C}_{1}} + \frac{1}{{C}_{2}}} + {C}_{12} ,$$

denoted by formula (1).

When the length of the tunable coupler of floating ground type becomes longer, C₁ and C₂ will increase accordingly, and at this time, C_{eff} will increase accordingly.

Further, the eigenfrequency f of the tunable coupler of floating ground type is:

$$f = \frac{1}{2 π \sqrt{( {L}_{J} {C}_{e f f} )}} ,$$

denoted by Formula (2).

As can be seen, when the element inductance value L_{J} in the tunable coupler of floating ground type is determined, the larger the C_{eff}, the less the eigenfrequency f of the tunable coupler of floating ground type, so that the above-mentioned frequency condition can be satisfied.

Moreover, under the long distance condition, the tunable coupler of floating ground type of the solution of the present disclosure can satisfy the turning-off condition of coupling between two qubits, and can provide a certain coupling strength when the coupling is turned on.

Further, the tunable coupler of floating ground type described in the solution of the present disclosure will be verified by specific examples below; and specifically, the configuration shown in FIG. 1 is adopted, and the specific parameters are as shown in FIG. 5, where the unit is um (micrometer). As shown in FIG. 5, the two electrode plates have the same shape and size, the body lengths of the two electrode plates are both 2000 um, the lengths of the strong coupling ports (i.e., the first coupling port 1011 of the first electrode plate and the four coupling port 1022 of the second electrode plate) are both 400 um, the lengths of the weak coupling ports (i.e., the second coupling port 1012 of the first electrode plate and the third coupling port 1021 of the second electrode plate) are both 200 um, the widths of all the coupling ports are 50 um, the distance between the two electrode plates is 100 um, the longitudinal distance between each electrode plate and the ground is 150 um, the horizontal distance between each electrode plate and the ground is 5 um, and the distance between plates at the coupling ports is 20 um.

Further, based on the sizes in FIG. 5 and the size of two qubits (such as qubit Q1 and qubit Q2, generally about 500 um) coupled by the tunable coupler of floating ground type, the center distance between the two qubits may approach 3,000 um, and this distance can suppress the correlation error between qubits to the greatest extent.

Further, under the configuration with the sizes shown in FIG. 5, the capacitances of the two electrode plates to the ground obtained by electromagnetic simulation are C₁=C₂=153 fF (femtofarads), and the inter-plate capacitance is C₁₂=62 fF. Without loss of generality, a set of reasonable capacitance and inductance parameters of qubits is given (see the table below). The eigenfrequency of the qubit calculated according to the above parameters is 6.39 GHz, and the anharmonicity is 281 MHz, satisfying the characteristic parameter requirements of common qubits in the current industry.

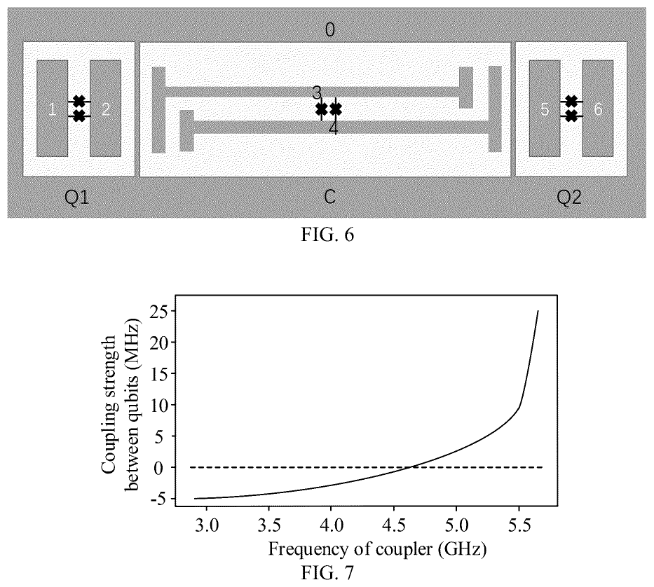

Further, in this example, the qubit of floating ground type similar to the structure of the tunable coupler of floating ground type is used to obtain a configuration of “qubit-coupler-qubit” as shown in FIG. 6. As shown in FIG. 6, 0 represents the grounded metal, 1 and 2 represent two electrode plates of the qubit Q1, 5 and 6 represent two electrode plates of the qubit Q2, and 3 and 4 represent two electrode plates of the tunable coupler C of floating ground type. Further, the capacitive coupling parameters between devices are represented by Cᵢⱼ, where the subscripts i and j range from 0 to 6. For example, C₀₁ represents the capacitance of the electrode plate 1 to ground, and C₁₂ represents the capacitance between the electrode plates 1 and 2; and the inductance parameters of devices are represented by Lₖ, where the subscript k is the device label Q1, C or Q2. The capacitance parameters and inductance parameters of qubits and the capacitance parameters of the tunable coupler of floating ground type obtained by electromagnetic simulation are given in the following table.

TABLE 1

| | | | Inductance | Capacitance | | | | | | |
|---|---|---|---|---|---|---|---|---|---|---|
| Capacitance Parameter of | | | Parameter | Parameter of | | | Coupling Capacitance Parameter of | | | |
| Qubit | | | of Qubit | Coupler | | | Qubit and Coupler | | | |
| (fF) | | | (nH) | (fF) | | | (fF) | | | |
| C₀₁, C₀₆ | C₀₂, C₀₅ | C₁₂, C₅₆ | L_{Q1}, L_{Q2} | C₀₃ | C₀₄ | C₃₄ | C₁₃, C₄₆ | C₁₄, C₃₆ | C₂₃, C₄₅ | C₂₄, C₃₅ |
| 120, | 120, | 5, 5 | 9, 9 | 153 | 153 | 62 | 0.23, | 0.11, | 17, 17 | 2.7, 2.7 |
| 120 | 120 | | | | | | 0.23 | 0.11 | | |

As can be seen from the above table, in the “Qubit-Coupler-Qubit” structure, the coupling strength between qubits is controlled by applying a direct-current (DC) signal to the tunable coupler of floating ground type (and adjusting the frequency of the tunable coupler of floating ground type).

Further, FIG. 7 shows a schematic diagram of the characteristic of adjusting the frequency of the tunable coupler of floating ground type to change the coupling strength between two qubits. As can be seen from FIG. 7, the frequency of the tunable coupler of floating ground type has a turning-off point of coupling near 4.6 GHz, from where when the frequency of the tunable coupler of floating ground type continues to increase or decrease, the coupling can be turned on, and a certain coupling strength (absolute value) can be provided. At the same time, it is also noted that the frequency of the tunable coupler of floating ground type when the coupling is turned off and on is less than the frequency of the qubits.

The above example is sufficient to illustrate that the tunable coupler configuration of floating ground type in the solution of the present disclosure can, under the condition of long-distance coupling of qubits, satisfy the frequency condition of turning on and off the coupling between two qubits when the frequency of the tunable coupler of floating ground type is less than the frequency of the qubits.

It should be noted that, in order to adjust the coupling strength between qubits, the capacitance parameters can also be changed by fine-tuning the sizes of components at the design level, in addition to adding a DC signal to equivalently adjust the frequency of the tunable coupler of floating ground type at the experimental level, so as to realize the regulation of the coupling strength.

In the above example, with the coupler configuration of the solution of the present disclosure, there are as many as 17 capacitive parameters that can be adjusted (see Table 1). It can be seen that the tunable coupler of floating ground type in the solution of the present disclosure is more universal and more applicable to the case of long-distance coupling between qubits than other general coupler configurations. The solution of the present disclosure provides a new technical route for the design and development of the high-performance superconducting quantum chip.

Thus, compared with the existing tunable coupler configuration, the core advantages of the tunable coupler configuration of floating ground type in the solution of the present disclosure are as follows: this tunable coupler configuration can be better applicable to the case of long-distance coupling of qubits, so that the superconducting quantum chip can use the long-distance coupling architecture and can also give full play to the huge advantages of this architecture to reduce the crosstalk and correlation error and expand the space for wiring and device distribution, thereby improving the performance of the quantum chip and also making the design of the quantum chip more free, simple and convenient.

Specifically, the solution of the present disclosure has the following advantages.
1. Highly wide applicability. Compared with other tunable coupler configurations, the solution of the present disclosure is more suitable for the case of long-distance coupling of qubits. The tunable coupler of floating ground type described in the solution of the present disclosure can realize the coupling of two qubits in the interval in which the frequency of the tunable coupler of floating ground type is lower than that of qubits, and can realize turning on and off the coupling of two qubits. Moreover, for the tunable coupler of floating ground type provided in the solution of the present disclosure, the longer the distance, the larger the capacitance and the lower its own frequency, so that the frequency condition of coupling of qubits can be better satisfied, and on this basis, the coupling requirement of qubits, including the turning-off condition and the certain coupling strength, can be better satisfied.
2. The performance of the quantum chip can be improved. The superconducting quantum chip using the tunable coupler configuration of floating ground type in the solution of the present disclosure may use the long-distance coupling architecture, thus, on the one hand, helping to reduce the control crosstalk and correlation error between qubits; and on the other hand, also providing a wide range of space for distribution of devices. For example, each qubit can have an independent read cavity and filter, reducing the read crosstalk between qubits, and thus improving the performance of the quantum chip greatly.
3. Help to expand the scale of the quantum chip. The superconducting quantum chip using the tunable coupler configuration of floating ground type in the solution of the present disclosure can use the long-distance coupling architecture, so the superconducting quantum chip has a larger wiring space, and the quantity of qubits can be further increased (the quantity of measurement and control lines will increase as the quantity of qubits increases), thereby increasing the scale of the chip.
4. Simplify the design requirements of the quantum chip. After adopting the tunable coupler configuration of floating ground type in the solution of the present disclosure, each qubit has space to place an independent read cavity and filter, so there is no need to design a read cavity or filter multiplexed by multiple qubits, thus reducing the design complexity of the quantum chip greatly.

The foregoing specific implementations do not constitute a limitation on the protection scope of the present disclosure. Those having ordinary skill in the art will appreciate that various modifications, combinations, sub-combinations and substitutions may be made according to a design requirement and other factors. Any modification, equivalent replacement, improvement or the like made within the spirit and principle of the present disclosure shall be included in the protection scope of the present disclosure.

What is claimed is:

1. A coupling component applied to a quantum chip, comprising:
a first electrode plate; and
a second electrode plate electrically connected to the first electrode plate;
wherein the first electrode plate comprises a first coupling port disposed at a first end of the first electrode plate and a second coupling port disposed at a second end of the first electrode plate; and the first coupling port is used to couple a first qubit, and the second coupling port is used to couple a second qubit; and
the second electrode plate comprises a third coupling port disposed at a first end of the second electrode plate and a fourth coupling port disposed at a second end of the second electrode plate; and the third coupling port is used to couple the first qubit, and the fourth coupling port is used to couple the second qubit;
wherein formed coupling strengths satisfy at least one of:
a first coupling strength formed by coupling the first coupling port with the first qubit is different from a second coupling strength formed by coupling the second coupling port with the second qubit; and
a third coupling strength formed by coupling the third coupling port with the first qubit is different from a fourth coupling strength formed by coupling the fourth coupling port with the second qubit.

2. The coupling component of claim 1, wherein the first coupling strength is greater than the second coupling strength or the first coupling strength is less than the second coupling strength.

3. The coupling component of claim 1, wherein the third coupling strength is greater than the fourth coupling strength or the third coupling strength is less than the fourth coupling strength.

4. The coupling component of claim 1, wherein a total coupling strength formed by the coupling component and the first qubit is identical to a total coupling strength formed by the coupling component and the second qubit;
wherein the coupling component is a symmetrical coupler.

5. The coupling component of claim 1, wherein the first electrode plate and the second electrode plate are arranged at interval in a first direction.

6. The coupling component of claim 5, wherein a first orthographic projection of the first electrode plate on a specific plane at least partially overlaps with a second orthographic projection of the second electrode plate on the specific plane, wherein the specific plane is perpendicular to the first direction.

7. The coupling component of claim 5, wherein a body of the first electrode plate extends in a second direction different from the first direction, so that the first end of the first electrode plate and the second end of the first electrode plate are arranged in the second direction.

8. The coupling component of claim 7, wherein the first coupling port and the third coupling port for coupling with the first qubit are aligned or misaligned in the first direction.

9. The coupling component of claim 5, wherein a body of the second electrode plate extends in a second direction different from the first direction, so that the first end of the second electrode plate and the second end of the second electrode plate are arranged in the second direction.

10. The coupling component of claim 9, wherein the second coupling port and the fourth coupling port for coupling with the second qubit are aligned or misaligned in the first direction.

11. The coupling component of claim 1, further comprising:
a quantum interference device arranged between the first electrode plate and the second electrode plate and configured to electrically connect the first electrode plate to the second electrode plate.

12. The coupling component of claim 11, wherein the quantum interference device comprises two Josephson junction chains in parallel; wherein a Josephson junction chain is connected to the first electrode plate and the second electrode plate respectively;
wherein the Josephson junction chain contains at least one Josephson junction.

13. The coupling component of claim 12, wherein, in a case of the Josephson junction chain contains two or more Josephson junctions, the two or more Josephson junctions are connected in series.

14. The coupling component of claim 12, wherein quantities of Josephson junctions contained in different Josephson junction chains are same or different.

15. The coupling component of claim 11, wherein a coplanar capacitance is capable of being formed between the first electrode plate and the second electrode plate.

16. The coupling component of claim 11, wherein
a frequency adjustment of the coupling component is capable of adjusting a coupling strength between the first qubit and the second qubit during operation of the coupling component; or
the frequency adjustment of the coupling component is capable of turning on or off coupling between the first qubit and the second qubit during operation of the coupling component.

17. The coupling component of claim 16, wherein an adjustment of a magnetic flux of the quantum interference device is capable of adjusting a frequency of the coupling component during operation of the coupling component.

18. The coupling component of claim 1, further comprising:
an external electrode plate for grounding; wherein the external electrode plate is arranged on periphery of the first electrode plate and the second electrode plate, and surrounds the first electrode plate and the second electrode plate to form a floating ground structure;
wherein the coupling component is a floating ground coupler.

19. A quantum chip, comprising:
a coupling component, a first qubit and a second qubit;
wherein the coupling component comprises:
a first electrode plate; and
a second electrode plate electrically connected to the first electrode plate;
wherein the first electrode plate comprises a first coupling port disposed at a first end of the first electrode plate and a second coupling port disposed at a second end of the first electrode plate; and the first coupling port is used to couple the first qubit, and the second coupling port is used to couple the second qubit; and
the second electrode plate comprises a third coupling port disposed at a first end of the second electrode plate and a fourth coupling port disposed at a second end of the second electrode plate; and the third coupling port is used to couple the first qubit, and the fourth coupling port is used to couple the second qubit;
wherein formed coupling strengths satisfy at least one of:
a first coupling strength formed by coupling the first coupling port with the first qubit is different from a second coupling strength formed by coupling the second coupling port with the second qubit; and
a third coupling strength formed by coupling the third coupling port with the first qubit is different from a fourth coupling strength formed by coupling the fourth coupling port with the second qubit.

20. A quantum computing device, comprising:
a quantum chip, and a controller configured to control the quantum chip;
wherein the quantum chip comprises: a coupling component, a first qubit and a second qubit;
wherein the coupling component comprises:
a first electrode plate; and
a second electrode plate electrically connected to the first electrode plate;
wherein the first electrode plate comprises a first coupling port disposed at a first end of the first electrode plate and a second coupling port disposed at a second end of the first electrode plate; and the first coupling port is used to couple the first qubit, and the second coupling port is used to couple the second qubit; and
the second electrode plate comprises a third coupling port disposed at a first end of the second electrode plate and a fourth coupling port disposed at a second end of the second electrode plate; and the third coupling port is used to couple the first qubit, and the fourth coupling port is used to couple the second qubit;
wherein formed coupling strengths satisfy at least one of:
a first coupling strength formed by coupling the first coupling port with the first qubit is different from a second coupling strength formed by coupling the second coupling port with the second qubit; and
a third coupling strength formed by coupling the third coupling port with the first qubit is different from a fourth coupling strength formed by coupling the fourth coupling port with the second qubit.
